(19) United States
(12) Patent Application Publication
(10) Pub. No.: US 2018/0149685 A1
(43) Pub. Date: May 31, 2018

(54) SENSOR AND SENSOR SYSTEM

(71) Applicants: Makito NAKASHIMA, Kanagawa (JP); Tsuneaki KONDOH, Kanagawa (JP); Tomoaki SUGAWARA, Kanagawa (JP); Junichiro NATORI, Kanagawa (JP); Yuko ARIZUMI, Kanagawa (JP); Mayuka ARAUMI, Tokyo (JP); Hideyuki MIYAZAWA, Kanagawa (JP); Kimio AOKI, Shizuoka (JP); Takahiro IMAI, Tokyo (JP); Mizuki OTAGIRI, Kanagawa (JP); Megumi KITAMURA, Kanagawa (JP); Yuki HOSHIKAWA, Kanagawa (JP)

(72) Inventors: Makito NAKASHIMA, Kanagawa (JP); Tsuneaki KONDOH, Kanagawa (JP); Tomoaki SUGAWARA, Kanagawa (JP); Junichiro NATORI, Kanagawa (JP); Yuko ARIZUMI, Kanagawa (JP); Mayuka ARAUMI, Tokyo (JP); Hideyuki MIYAZAWA, Kanagawa (JP); Kimio AOKI, Shizuoka (JP); Takahiro IMAI, Tokyo (JP); Mizuki OTAGIRI, Kanagawa (JP); Megumi KITAMURA, Kanagawa (JP); Yuki HOSHIKAWA, Kanagawa (JP)

(21) Appl. No.: 15/823,751

(22) Filed: Nov. 28, 2017

(30) Foreign Application Priority Data
Nov. 28, 2016 (JP) 2016-230395

(51) Int. Cl. G01R 29/08; G01D 21/02; G01R 1/067; G01G 21/00

(52) U.S. Cl. CPC G01R 29/0814; G01D 21/02; G01R 29/0892; G01G 21/00; G01R 1/06794

(57) ABSTRACT

A sensor includes a first detector and a second detector. The first detector detects an electromagnetic noise varying according to a distance between the sensor and a human body and changes an output according to the electromagnetic noise detected. The second detector detects a detection load applied to a detection surface of the sensor and changes an output according to the detection load.

### CROSS-REFERENCE TO RELATED APPLICATION

This patent application is based on and claims priority pursuant to 35 U.S.C. § 119(a) to Japanese Patent Application No. 2016-230395, filed on Nov. 28, 2016, in the Japan Patent Office, the entire disclosure of which is hereby incorporated by reference herein.

### BACKGROUND

### Technical Field

Aspects of the present disclosure relate to a sensor and a sensor system.

### Description of the Related Art

There is a sensor which detects a contact state between a human body or an object other than the human body to be detected and any other target. For example, when a sensor is disposed in a seat (chair) serving as any target and a human body (person) to be detected is seated on the seat, a sensor detects a change in pressure and outputs a signal according to a detection result to make it possible to detect a seated state. In another example, a sensor detects a change in electrostatic capacity when a human body (person) or an object to be detected moves close to or away from any target, and the sensor outputs a signal according to a detection result to make it possible to detect that the human body or the object moves close or away.

### SUMMARY

In an aspect of the present disclosure, there is provided a sensor that includes a first detector and a second detector. The first detector detects an electromagnetic noise varying according to a distance between the sensor and a human body and changes an output according to the electromagnetic noise detected. The second detector detects a detection load of the sensor applied to a detection surface and changes an output according to the detection load.

In another aspect of the present disclosure, there is provided a sensor system that includes the sensor according and a controller. The controller determines a detection target in contact with the detection surface according to an output from the sensor.

### BRIEF DESCRIPTION OF THE SEVERAL VIEWS OF THE DRAWINGS

A more complete appreciation of the disclosure and many of the attendant advantages and features thereof can be readily obtained and understood from the following detailed description with reference to the accompanying drawings, wherein:

FIG. 1 is a view illustrating a sensor system according to an embodiment of the present disclosure;

FIG. 2 is a view illustrating a sensor according to an embodiment of the present disclosure;

FIG. 3 is a block diagram illustrating a configuration of a control system of the sensor system according the embodiment of the present disclosure;

FIG. 4 is a flowchart illustrating determination processing according to an embodiment of the present disclosure, executed in the sensor system according the embodiment of the present disclosure;

FIG. 5 is a view illustrating a form in which the sensor system according the embodiment of the present disclosure is used for another system;

FIG. 6A is a view illustrating a state in which a sensor detects seating of a human to be detected;

FIG. 6B is a view illustrating a state in which a sensor detects placement of an object other than a human;

FIG. 7 is a view illustrating an example of a detection result displayed on a display of the system of FIG. 5;

FIG. 8 is a diagram illustrating output characteristics output when a first detector detects a human body; and

FIG. 9 is a diagram illustrating output characteristics output when the first detector does not detect a human body.

The accompanying drawings are intended to depict embodiments of the present disclosure and should not be interpreted to limit the scope thereof. The accompanying drawings are not to be considered as drawn to scale unless explicitly noted.

### DETAILED DESCRIPTION

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Hereinafter, an embodiment of the present disclosure will be described with reference to the drawings. In the embodiment, components having the same function and the same configuration are denoted by the same reference numerals, and redundant description will be omitted appropriately. Some drawings may be partially omitted in order to assist in understanding a configuration.

A sensor system 1 according to an aspect of the present disclosure includes a sensor 2 and a controller 100. The sensor 2 includes a human body detection sensor 3 as a first detector capable of detecting a human body and a load detection sensor 4 as a second detector capable of detecting a detection load F. The human body detection sensor 3 is coupled to the controller 100 via an A/D converter 110 and a signal line. The load detection sensor 4 is coupled to the controller 100 via an A/D converter 120 and a signal line. The controller 100 is coupled to a power source (commercial power source AC) 130 for driving a system. In the present embodiment, the sensor 2 and the A/D converters 110 and 120 constitute a sensor module 5 in a case where the A/D converters 110 and 120 are removed from the sensor module 5, the sensor 2 itself becomes a sensor module.

In the present embodiment, the human body detection sensor 3 and the load detection sensor 4 are laminated in contact with each other to form a laminated structure. However, a laminated structure in which a gap is formed between the human body detection sensor 3 and the load detection sensor 4 may be used.

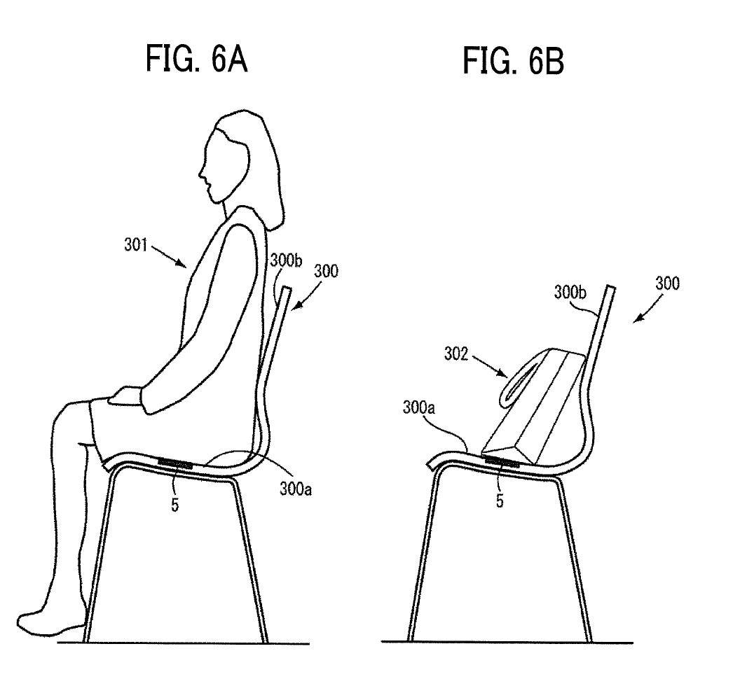

The sensor 2 has a detection surface 2A illustrated in FIG. 2. The sensor 2 is disposed at any place such that a human body 301 or an object 302 to be detected comes into contact with this detection surface 2A, and the detection load F is input from the detection surface 2A. For the human body 301 and the object 302, see FIG. 6.

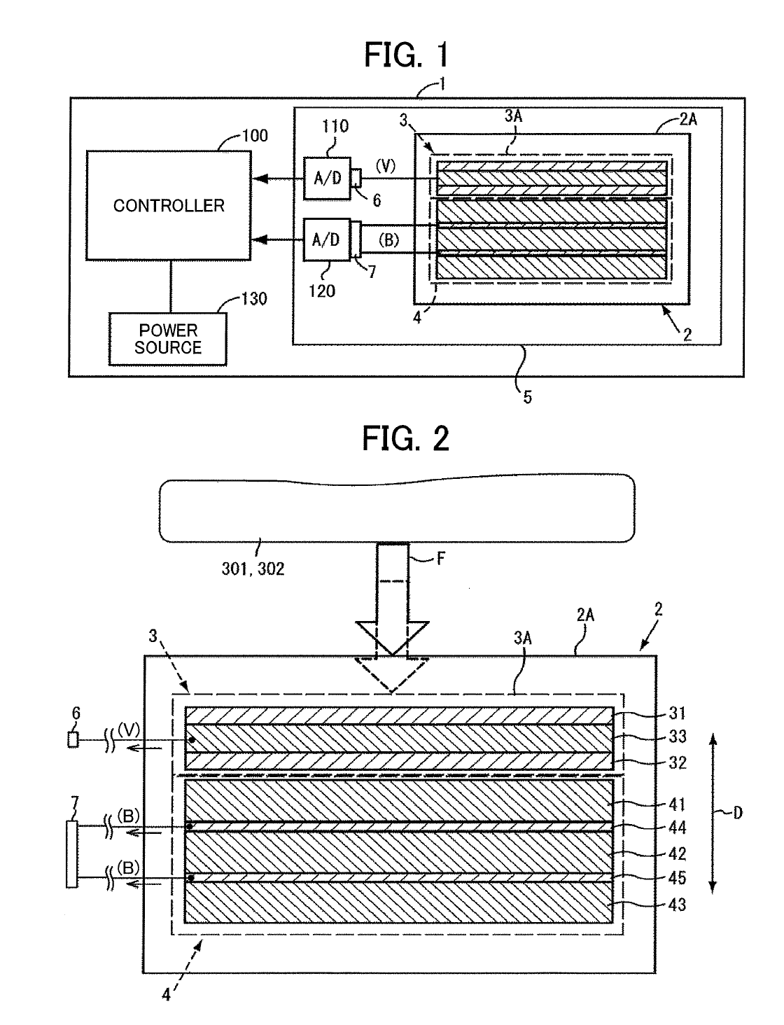

As illustrated in FIG. 2, the human body detection sensor 3 includes a detection electrode 33 sandwiched between film substrates 31 and 32. The human body detection sensor 3 is covered with a cover member 3A. The human body detection sensor 3 detects a hum noise generated when the human body 301 moves close to or away from the detection electrode 33. When detecting a hum noise, the detection electrode 33 outputs a voltage. This output is taken as a detection electrode voltage V. The detection electrode voltage V is converted from an analog signal into a digital signal by the A/D converter 110 of FIG. 1 to be input to the controller 100. That is, the human body detection sensor 3 includes the detection electrode 33 which detects an electromagnetic noise varying according to a distance between the human body detection sensor 3 and the human body 301, and an output (detection electrode voltage V) varies according to the detected electromagnetic noise.

The load detection sensor 4 is a so-called electrostatic capacity pressure sensor, and has dielectric layers 41, 42, and 43, and electrodes 44 and 45 laminated alternately to form a pressure sensor sheet. The lamination number of the dielectric layers 41, 42, and 43, and the electrodes 44 and 45 is not limited to the lamination number of the embodiment, and can be arbitrarily selected. When detecting a pressure, the electrodes 44 and 45 output a voltage signal. This output is taken as an electrostatic electrode sensor output B. The electrostatic electrode sensor output B is converted from an analog signal into a digital signal by the A/D converter 120 of FIG. 1 to be input to the controller 100. That is, the load detection sensor 4 detects the detection load F applied to the detection surface 2A, and the electrostatic electrode sensor output B changes according to the detection load F.

In the present embodiment, the dielectric layer 42 of the load detection sensor 4 is constituted by a flexible member, for example, a rubber sheet to form an intermediate layer, and has the electrodes 44 and 45 laminated on both surfaces. As such an element, for example, a pressure sensor can be used that employs an elastic member for both a dielectric layer and an electrode. Each of the electrodes of the sensor has a structure obtained by laminating a conductive rubber on the dielectric layer, and detects a load based on an electrostatic capacity characteristic at an intersecting portion (referred to as a cell) of the electrodes facing each other.

In another form of the load detection sensor used in the present embodiment, each of the dielectric layers 41, 42, and 43 of the load detection sensor 4 is constituted by a flexible member, for example, a rubber sheet to form an intermediate layer, and is in contact with both surfaces of each of the electrodes 44 and 45. The load detection sensor 4 is an element which bends when the detection load F from a direction perpendicular to lamination surfaces of the dielectric layers 41, 42, and 43, and the electrodes 44 and 45 is applied to the load detection sensor 4, and generates a signal by frictional charging caused between the dielectric layers 41, 42, and 43, and the electrodes 44 and 45. That is, the load detection sensor 4 has the dielectric layers 41, 42, and 43, and the pair of electrodes 44 and 45 facing each other via the dielectric layers 41, 42, and 43, and at least the dielectric layers 41, 42, and 43 have flexibility.

In the present embodiment, a hum noise derived from the commercial power source 130 via the human body 301 is input from the detection electrode 33 of the human body detection sensor 3 to the controller 100 as a voltage characteristic, and a contact state between the human body 301 and the detection surface 2A is determined based on comparison of the voltage characteristic as a preset first determination value with a threshold V1, but contact with the object 302 is not detected. In addition, in the electrodes 44 and 45 (load detection sensor 4), a central processing unit (CPU) 101 of the controller 100 calculates an electrostatic capacity characteristic due to contact/pressing of a detection target into a load, and determines a load characteristic of the detection target based on comparison of the electrostatic capacity characteristic as a second determination value preset in the controller 100 with a threshold C2. Furthermore, the CPU 101 of the controller 100 determines whether a detection target in contact with the detection surface 2A of the sensor 2 is the human body 301 or the object 302 based on the voltage characteristic of the detection electrode 33 and the electrostatic capacity characteristic of the load detection sensor 4.

In this way, it is possible to provide a sensor which can accurately detect a detection target even when the detection target is the human body 301 or the object 302 other than the human body 301 because of inclusion of the (human body detection sensor 3) and the (load detection sensor 4) in one sensor 2.

Next, a configuration of the sensor 2 will be described in detail.

Preferably, a material of the detection electrode 33 has a low electric resistance, is thin and flexible, and does not cause the human body 301 to be detected to feel discomfort due to feeling of presence of a sensor even when the human body 301 comes into contact with or is pressed against the sensor. For example, an electrode in which a metal such as nickel copper is formed on a surface of a polyester nonwoven fabric by a method such as plating coating can be used.

It is known that the human body 301 is represented by a circuit model in which a capacitor of 100 pF is coupled to a resistor of 1.5 kΩ in series. Electrostatic capacitive coupling between the human body 301 and the detection electrode 33 occurs via a cushion cloth, clothing, or the like, and a voltage characteristic of the detection electrode 33 changes. Herein, the electrostatic capacity of the human body 301 varies according to an individual. Therefore, an output voltage value varies according to the electrostatic capacity. However, in reality, the electrostatic capacity of the human body 301 varies according to an individual. Therefore, some people have a large change in electrostatic capacity and some people have a small change in electrostatic capacity. Therefore, the electrostatic capacity of the cover member 3A covering the detection electrode 33 of the human body detection sensor 3 is preferably small. By setting the electrostatic capacity of the cover member 3A to about one tenth of the capacity of the human body 301, in the total electrostatic capacity due to contact with the human body 301, the cover member 3A is dominant. Therefore, the voltage characteristic due to a difference in electrostatic capacity among individuals hardly fluctuates, and it is possible to reliably determine proximity/separation of the human body 301. The cover member 3A is preferably disposed from a viewpoint of preventing corrosion of the detection electrode 33, and a conventionally known waterproof film can be used.

The film substrates 31 and 32 are bonded to interfaces (facing surfaces) of the detection electrode 33, respectively. A conventionally known adhesive and bonding method can be used. As disposition of the detection electrode 33, the detection electrode 33 is preferably disposed closer to the detection surface 2A of the sensor 2. A change in electrostatic capacity due to contact with a human body is larger, and therefore the voltage characteristic can be increased. This makes it possible to reliably detel mine contact/separation of a human.

As the load detection sensor 4 serving as an electrostatic capacity pressure sensor, a conventionally known pressure sensor can be used. However, other representative examples include a sensor using a semiconductor, a sensor using a contact resistance, a sensor using a conductive rubber, and a sensor using a piezoelectric polymer film. The load detection sensor 4 according to the present embodiment is thin and flexible.

Generally, in an electrostatic capacity type sensor, a pair of electrodes facing each other is disposed on both surfaces of a dielectric layer, and a surface is covered with an insulating sheet. For example, such a sensor uses an elastic member for both an electrode and a dielectric layer. Each of the electrodes of the sensor has a structure obtained by sandwiching the dielectric layer by a conductive rubber, and detects a load based on an electrostatic capacity characteristic at an intersecting portion (referred to as a cell) of the electrodes facing each other.

As a method for detecting the detection load F with the load detection sensor 4, a method for detecting an electrostatic capacity of the electrode intersecting portion (cell) by deformation of the dielectric layer 42 can be used. The load detection sensor 4 of the present embodiment is made of a flexible material. Therefore, as illustrated in FIG. 2, when the load detection sensor 4 receives the detection load F, the dielectric layer 42 is deformed, and a distance between the electrodes 44 and 45 changes. At this time, when the electrodes 44 and 45 facing each other are equally deformed in a thickness direction D, an electrostatic capacity C between the electrodes 44 and 45 is expressed by Formula 1 using a function of a displacement z in the thickness direction D of the load detection sensor 4 (sensor 2).

Formula 1

C=ε0εrS/d−z (1)

Herein, ε0 represents a dielectric constant of vacuum, εr represents a relative dielectric constant of a dielectric layer, S represents an electrode area of a cell, and d represents an initial thickness of a dielectric layer (initial distance between electrodes). Assuming that the displacement z is due to a load P in a normal direction, received by the load detection sensor 4 and P=f(z), the electrostatic capacity C is expressed as a function of the load P as in Formula 2.

Formula 2

C(P)=ε0εS/(d0−f−1[z]) (2)

Formula 3 is obtained by deforming Formula 2, and the load P can be calculated by detecting the electrostatic capacity C of a cell.

Formula 3

Pf(d0−ε0εrS/C) (3)

When the electrodes 44 and 45 facing each other are disposed in a plurality of electrode groups, a load distribution can be also detected by detecting an electrostatic capacity in each of cells facing each other. In this case, the electrodes facing each other are preferably disposed as electrode groups in a matrix.

The load detection sensor 4 has a characteristic that spatial resolution and measurement accuracy have a relation of trade-off. The spatial resolution is the area of the intersecting portion (cell) of the electrodes 44 and 45 facing each other. In order to have flexibility, the dielectric layers 41, 42, and 43 are desirably made of a polymer material. However, the polymer material has a small relative dielectric constant, and therefore has a small electrostatic capacity. Therefore, it is difficult to increase an S/N ratio unless the cell area is secured by increasing an electrode width to a certain value or more. Meanwhile, if the electrode width is increased in order to increase the S/N ratio, each cell area is increased, and therefore the spatial resolution is reduced.

As a method for forming the electrodes 44 and 45, for example, a conductive rubber ink can be formed by a known printing method. For example, as the printing method, screen printing or the like is a typical example. The screen printing patterns a plate into a desired shape using a photosensitive emulsion, and therefore can cope with a complicated electrode shape and can easily make the electrode large. Lead-out wiring (signal line leading to the controller 100) of the sensor 2 preferably has flexibility, and lead-out wiring similar to the lead-out wiring in the detection electrode 33 can be used. An end of the wiring only needs to be able to be coupled to a connector 7 with the controller 100.

When electrode groups facing one another are disposed in a matrix, it is preferable to design a wiring pitch and the number of wires such that the end of the wiring can be electrically coupled to a known flexible printed wiring board. A known printed wiring board can be used. Also as for coupling to the lead-out wiring, coupling to the connector 7 is possible using known crimping or the like. The load detection sensor 4 is easily influenced by a noise. Therefore, a shield electrode may be disposed in order to reduce a noise mixed in the load detection sensor 4.

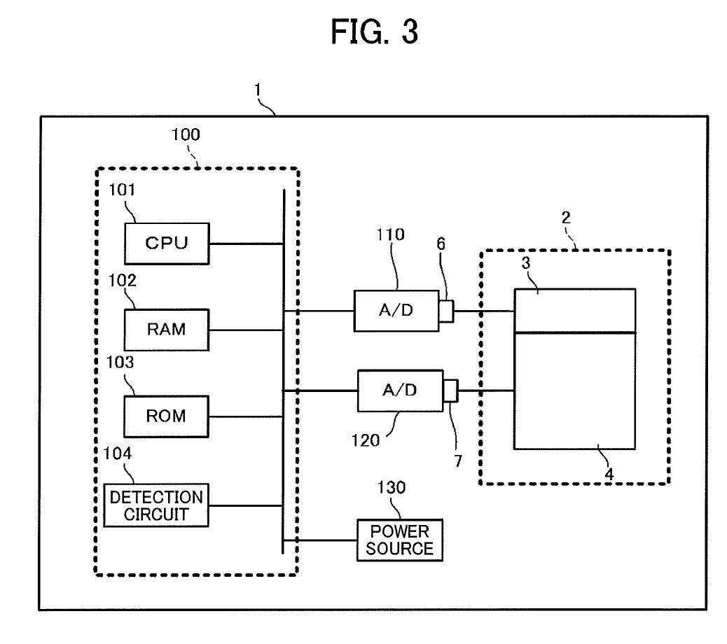

Next, a foist of coupling between the sensor 2 and the controller 100 will be described with reference to FIGS. 2 and 3. The detection electrode 33 is coupled to a connector 6 via a signal line, and the connector 6 is further coupled to the A/D converter 110. Similarly, the electrodes 44 and 45 of the load detection sensor 4 are also coupled to the connector 7 via connection lines, and the connector 7 is further coupled to the A/D converter 120. The A/D converters 110 and 120 to which the detection electrode 33 (human body detection sensor 3) and the load detection sensor 4 are coupled, respectively, are each coupled to the controller 100.

As illustrated in FIG. 3, the controller 100 is an electronic control circuit including the CPU 101 serving as a central calculator, a random access memory (RAM) 102 and a read only memory (ROM) 103 serving as storage, a detection circuit 104, and the like. The ROM 103 stores, in advance, a threshold V as a determination value of a voltage characteristic of the detection electrode 33 used for determining whether a detection target is the human body 301, and thresholds C1 and C2 as determination values of an electrostatic capacity characteristic of the load detection sensor 4 used for determining presence or absence of a load state or the type of the load.

In the present embodiment, the type of the detection load F includes an adult and a child, for example. The threshold C1 is a threshold for discrimination between an adult and a child. The threshold C2 is a threshold for discrimination between the object 302 and no load.

The detection circuit 104 detects the detection electrode voltage V (voltage signal) generated by electrostatic capacitive coupling due to approach or proximity of the human body 301 to the detection electrode 33 (human body detection sensor 3).

The CPU 101 has a function of determining whether a detection target in contact with or close to the detection surface 2A is the human body 301 based on the detection electrode voltage V from the detection electrode 33 (human body detection sensor 3) and the threshold V1, a function of determining the type (adult or not) of the human body 301 and presence or absence of the object 302 based on the electrostatic electrode sensor output B output from the electrodes 44 and 45 (load detection sensor 4) and the thresholds C1 and C2, and a function as a calculator which detects electrostatic capacity of the load detection sensor 4 and calculates the electrostatic capacity into a load.

As a signal detection method in the detection electrode 33, an electromagnetic noise in a disposition environment is used. This electromagnetic noise is detected as a voltage characteristic according to a disposition environment of the detection electrode 33. However, the electromagnetic noise is not necessarily the same as the voltage characteristic. The detection electrode voltage V (output) varies due to an influence of stray capacitance or electromagnetic waves in a disposition environment.

A typical example of the electromagnetic noise is a periodic radio wave emitted from a commercial power source or an electronic device. The human body 301 receives the radio wave by electromagnetic induction. The human body 301 is close to or preferably in contact with the detection electrode 33. As a result, the electrostatic capacitive coupling is detected as a voltage characteristic. Therefore, the electromagnetic noise is often detected as a periodic voltage characteristic. However, in addition, a voltage value may also change due to electrostatic capacitive coupling between a stray capacitance of a metal, a dielectric, or the like present in a disposition environment and a human body. In order to reduce this influence of the stray capacitance, for example, it is preferable to shield the controller 100 with a metal casing or the like, or to cover a connection line with a conductive cover. As a result, a range of setting a threshold of a voltage as a determination value can be wider. Therefore, contact or separation of the human body 301 with respect to the detection surface 2A can be reliably detected, and a contact state of the object 302 is not detected. Therefore, contact of the human body 301 can be determined.

Therefore, as described above, the controller 100 preferably monitors an initial voltage value in a disposition environment in advance and sets a voltage threshold. Then, by inputting a voltage characteristic value generated by proximity or contact of the human body 301 to the controller 100 and comparing magnitude of the voltage characteristic value with the preset threshold V1 as a first determination value, a contact state and a seat-leaving state of the human body 301 can be reliably determined.

A known method for detecting an electrostatic capacity in the load detection sensor 4 can be used. For example, it is possible to use a method for detecting a change in electrostatic capacity by measuring a phase difference with respect to an amplitude and a voltage of a current flowing when a voltage with a constant amplitude is applied to a cell. This method has a large response speed and makes it possible to separate the electrostatic capacity of the cell from the resistance of electrode wiring, and therefore is effective particularly in a case where electrode groups are disposed in a matrix and it is desired to detect a pressure distribution in a plane.

In order to detect the detection load F, the detection circuit 104 included in the controller 100 extracts an electrostatic capacity based on the detected change in resistance and phase information, and the CPU 101 serving as a calculator calculates the electrostatic capacity into a load. By performing the following signal processing, for example, the CPU 101 can determine whether a contact target to the detection surface 2A is an adult or a child, the object 302 is placed, or there is nothing (a state in which nothing is placed).

That is, the controller 100 determines contact with the human body 301 and contact with the object 302 based on comparison between the detection electrode voltage V (output) from the human body detection sensor 3 and the threshold V1 as a preset first determination value, and determines a load characteristic of a detection target in contact with the detection surface 2A based on comparison between the electrostatic electrode sensor output B from the load detection sensor 4 and thresholds C1 and C2 as preset second determination values.

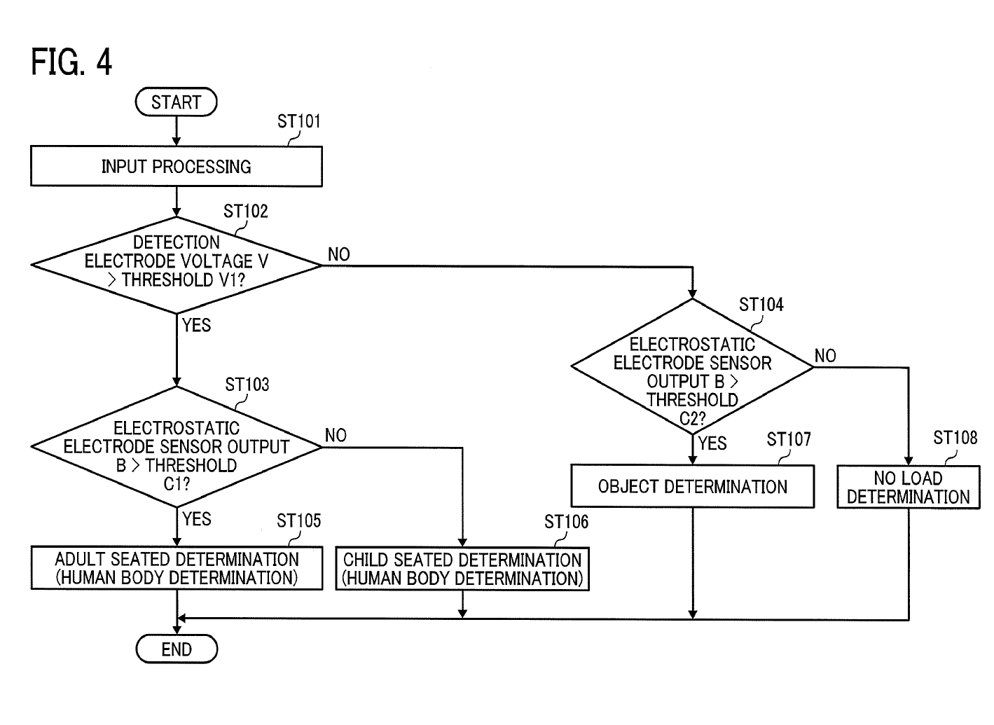

Control contents of the sensor system 1 having such a configuration will be described with reference to the flowchart illustrated in FIG. 4. The controller 100 repeatedly executes processing contents illustrated in the flowchart illustrated in FIG. 4 by predetermined interruption every predetermined time.

When the control shifts to this routine, in step ST101, the controller 100 executes input processing for reading the detection electrode voltage V of the detection electrode 33, the electrostatic electrode sensor output B from the electrodes 44 and 45 (load detection sensor 4), and the like.

In step ST102, the controller 100 compares the current detection electrode voltage V from the detection electrode 33 (human body detection sensor 3) with the threshold V1, and determines whether the detection electrode voltage V is larger than the threshold V1. The threshold V1 is set to a suitable value for detecting the human body 301 on the detection surface 2A in the human body 301 or the object 302.

In a case where the detection electrode voltage V exceeds the threshold V1, the controller 100 determines that the detection target is the human body 301, and the process proceeds to step ST103. In step ST103, the controller 100 compares the current electrostatic electrode sensor output B from the electrodes 44 and 45 (load detection sensor 4) with the threshold C1, and deter mines whether the electrostatic electrode sensor output B is larger than the threshold C1. This threshold C1 is set to a suitable value for discrimination between an adult and a child according to the detection load F (body weight).

In a case where the electrostatic electrode sensor output B exceeds the threshold C1, the detection load F applied to the load detection sensor 4 is large. Therefore, the process proceeds to step ST105, and the controller 100 makes a human body determination that the detection target is an adult. In step ST103, in a case where the electrostatic electrode sensor output B does not exceed the threshold C1, the detection load F applied to the load detection sensor 4 is small. Therefore, in step ST106, the controller 100 makes a human body determination that the detection target is a child.

Meanwhile, in step ST102, in a case where the detection electrode voltage V does not exceed the threshold V1, contact with a human body is not detected. Therefore, the controller 100 makes an object determination that the detection target is an object other than a human body, and the process proceeds to step ST104. In step ST104, the controller 100 compares the electrostatic electrode sensor output B from the electrodes 44 and 45 (load detection sensor 4) with the threshold C2, and determines whether the electrostatic electrode sensor output B is larger than the predetermined threshold C2. This threshold C2 is set to a suitable value for discrimination between a state in which the object 302 such as a baggage is placed and a state in which nothing is placed with the detection load F.

In a case where the electrostatic electrode sensor output B exceeds the threshold C2, the controller 100 assumes that the detection load F applied to the load detection sensor 4 is not the human body 301 but has a weight, and makes an object determination that, here in step ST107, the detection target is the object 302 other than the human body. In a case where the electrostatic electrode sensor output B does not exceed the threshold C2, the detection load F applied to the load detection sensor 4 is small. Therefore, in step ST108, the controller 100 makes a no load determination indicating a no load state in which nothing is placed. In the present embodiment, when the detection target is discriminated with respect to the detection surface 2A of the sensor 2 by determinations in any one of steps ST105 to ST108, the subsequent processing is completed.

As described above, in the configuration of the sensor system 1 including the sensor 2 having two functions of the human body detection sensor 3 and the load detection sensor 4, and the controller 100, the controller 100 discriminates whether an output of each of the human body detection sensor 3 and the load detection sensor 4 (each of the detection electrode voltage V and the electrostatic electrode sensor output B) is larger or smaller than the preset thresholds V1, C1, and C2. As a result, the sensor system 1 can accurately detect whether a detection target is the human body 301 or the object 302 other than the human body. That is, the sensor system 1 includes the first detector and the second detector which perform detection by different methods. Therefore, even if a detection target is the human body 301 or the object 302 other than the human body 301, detection can be accurately performed.

In a case where the electrodes 44 and 45 on the side of the load detection sensor 4 are divided as electrode groups, partial loads in each cell may be individually detected, and a surface pressure of a contact object (detection target) may be determined from the number (contact area) of the partial loads exceeding the threshold.

Next, an example of a work form to which the sensor 2 and the sensor system 1 according to an aspect of the present disclosure can be applied will be described.

In recent years, in offices of corporations and the like, the number of free address type offices in which an employee does not have a personal desk has increased. There is a request for grasping a use situation of each desk using a seating system which detects a seating state and a seat-leaving state with respect to a chair. For this purpose, in addition to the seated state and the seat-leaving state of an employee (human body), it is necessary to accurately grasp whether a detection target in contact with a seating surface of a chair is a human body or an object because an object other than a human body, such as a baggage of an employee is sometimes placed on the seating surface.

Examples of a seating sensor which detects contact with a human body or an object include a method using a pressure sensor to detect a load and a method for detecting proximity of a human body or an object using an electrostatic capacity type sensor. However, it may be difficult to discriminate individually between a seated state of a human body (employee/person) and a state of an object by these methods.

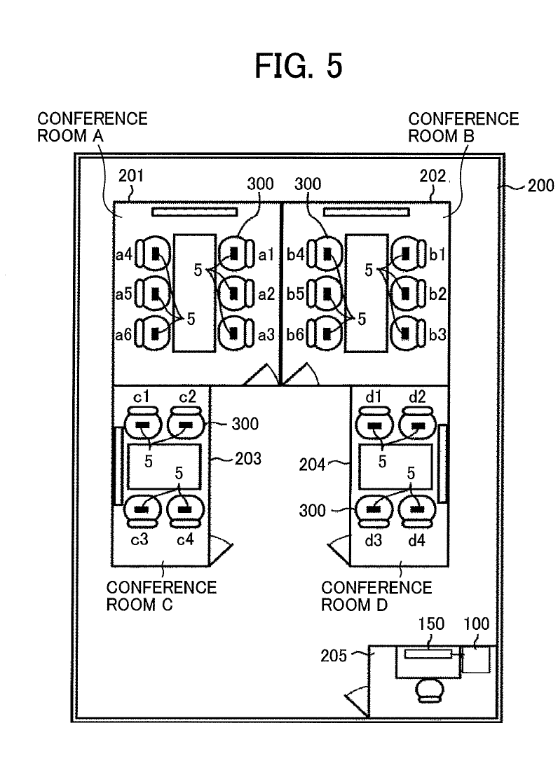

Therefore, FIG. 5 illustrates a form in which the above sensor system 1 is used for a seating system. The seating system illustrated in FIG. 5 is also a conference room management system, and detects occupancy ratios of a plurality of conference rooms 201, 202, 203, and 204 disposed in a building 200. The occupancy ratio used herein determines whether a conference room is being used by detecting, as illustrated in FIG. 6A, whether the human body (also referred to as person) 301 is seated on a chair 300 disposed in each conference room, and detecting, as illustrated in FIG. 6B, whether the object 302 such as a baggage is placed on the chair 300 instead of the human body 301.

In each of the plurality of chairs 300 disposed in the conference rooms 201 to 204, the sensor module 5 illustrated in FIG. 2 is disposed as a seating sensor on a seating surface 300a, as illustrated in FIGS. 6A and 6B. In this case, a detection target of the sensor module 5 includes the human body 301 (person) seated on the seating surface 300a of the chair 300 and the object 302 such as a baggage. The conference rooms 201 to 204 are denoted by identification reference numerals for specifying each of the conference rooms. Herein, for convenience, the conference rooms 201 to 204 are referred to as conference rooms A to D, respectively.

Each sensor module 5 can communicate with the controller 100 illustrated in FIG. 5 with a signal line or wirelessly. In a case where an output from the sensor module 5 is transmitted to the controller 100 wirelessly, it is only required to dispose a well-known transceiver on each sensor module 5 and on the side of the controller 100. The controller 100 is disposed in a system management room 205 different from the conference rooms 201 to 204, and is coupled to a display 150 such as a monitor.

On the system, each of the chairs 300 of the conference rooms is denoted by a unique identification number. For example, the plurality of chairs 300 six of which are disposed in each of the conference rooms 201 and 202 are denoted by identification numbers of a1 to a6 and b1 to b6, respectively. The plurality of chairs 300 four of which are disposed in each of the conference rooms 203 and 204 are denoted by identification numbers of c1 to c4 and d1 to d4, respectively. The controller 100 stores data while these identification numbers of the chairs 300 are associated with the sensor modules 5 disposed on the chairs 300. The controller 100 has a function of displaying statuses of the chairs 300 in the conference rooms 201 to 204 on the display 150.

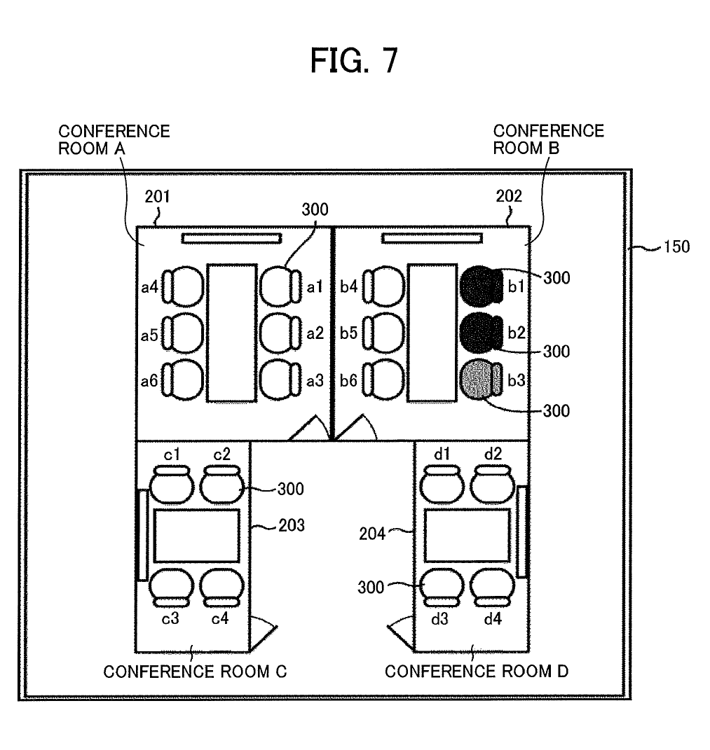

For example, in a case where an output from each sensor module 5 indicates that the human body 301 (person) such as an adult is seated on the seating surface 300a of the chair 300 as illustrated in FIG. 6A, the controller 100 has a function of changing a color of the chair 300 having the sensor module 5 which has issued the output and displaying the changed color as illustrated in FIG. 7. FIG. 7 illustrates a state in which the human body 301 (person) is seated on each of the chairs 300 denoted by the reference numerals b1 and b2.

For example, in a case where an output from each sensor module 5 indicates that the object 302 (baggage) is placed on the seating surface 300a of the chair 300 as illustrated in FIG. 6B, the controller 100 has a function of displaying the chair 300 having the sensor module 5 which has issued the output with a different color from the color of the human body 301 (person) as illustrated in FIG. 7. The example of FIG. 7 illustrates a state in which the object 302 (baggage) is placed on the chair 300 denoted by the reference numeral b3.

The controller 100 has a function of displaying the chair 300 having the sensor module 5 having no output colorlessly or with a different color from the case of seating or object placement as illustrated in FIG. 7.

The detection electrode 33 included in the human body detection sensor 3 of a seating sensor (sensor module 5) has a structure obtained by sandwiching a nonwoven fabric conductive sheet (electrode size 210 mm×140 mm) between PET substrates and laminating the resulting product at 80° C.

As the load detection sensor 4 serving as an electrostatic capacity sensor, an X3PRO sheet sensor manufactured by XSENSOR Technology Corporation (model number: PX 200, sensor number 5000 (100×50), sensor size 254 mm×127 mm, sensor pitch 5.08 mm, surface pressure measurement range 14 gf/cm² to 1054 gf/cm²) was used.

In this way, using the seating sensor (sensor module 5), for three states of an adult of 60 kg in weight, a baggage of 2 kg in weight, and no load, a monitoring test was performed in a state in which the human body 301 (person) was seated and a state in which the object 302 (baggage) was placed. The seating sensor (sensor module 5) was disposed on the wooden bench (chair) 300 without a cushion. As a comparative example, monitoring was performed similarly using the same electrostatic capacity sensor as described above without disposing the detection electrode 33. These execution results are summarized in Table 1.

<Monitoring Condition>

Detection electrode: PET 38 μm (manufactured by Toray Industries, Inc.: Lumirror T60)/conductive nonwoven fabric (manufactured by Seiren Co., Ltd.: conductive fabric Sui-10-30T, thickness 30 μm)/PET 38 μm (manufactured by Toray Industries, Inc.: Lumirror T60)

Pressure sensitive sensor: electrostatic capacity pressure sensor (manufactured by XSENSOR Technology Corporation, X3PRO sheet sensor, model number PX 200)

Human body detection: A detection electrode was coupled to an oscilloscope to monitor a voltage signal when a person is seated or leaves a seat. Oscilloscope: (manufactured by Lecroy Corporation) damping ratio 1:10

Load detection: An electrostatic capacity signal from an electrostatic capacity sensor was converted into a surface pressure and was displayed on the display 150. The maximum surface pressure is indicated in Table 1. Supplied software: X3 Professional 5.0

TABLE 1

| | | Pressure | | | | | | | |
|---|---|---|---|---|---|---|---|---|---|
| | | sensitive | | | | | | | Discrimination |
| | | sensor | | | | | Surface | | between |
| Execution | Detection | detected | Detection | | | Human | pressure | Load | human and |
| No. | electrode/area | area | target | Weight | | detection | gf/cm\hat{ }2 | detection | object |
| 1-1 | Conductive | 254 mm × | Adult | 60 | kg | ◯ | 0.380 | ◯ | ◯ |
| 1-2 | nonwoven | 127 mm | Baggage | 2 | kg | X | 0.070 | ◯ | |
| 1-3 | fabric | | No load | 0 | kg | X | 0 | X | |
| | \grave{ }270 mm × | | | | | | | | |
| | 140 mm | | | | | | | | |
| 2-1 | None | | Adult | 60 | kg | X | 0.380 | ◯ | X |
| 2-2 | | | Baggage | 2 | kg | X | 0.070 | ◯ | |
| 2-3 | | | No load | 0 | kg | X | 0 | X | |

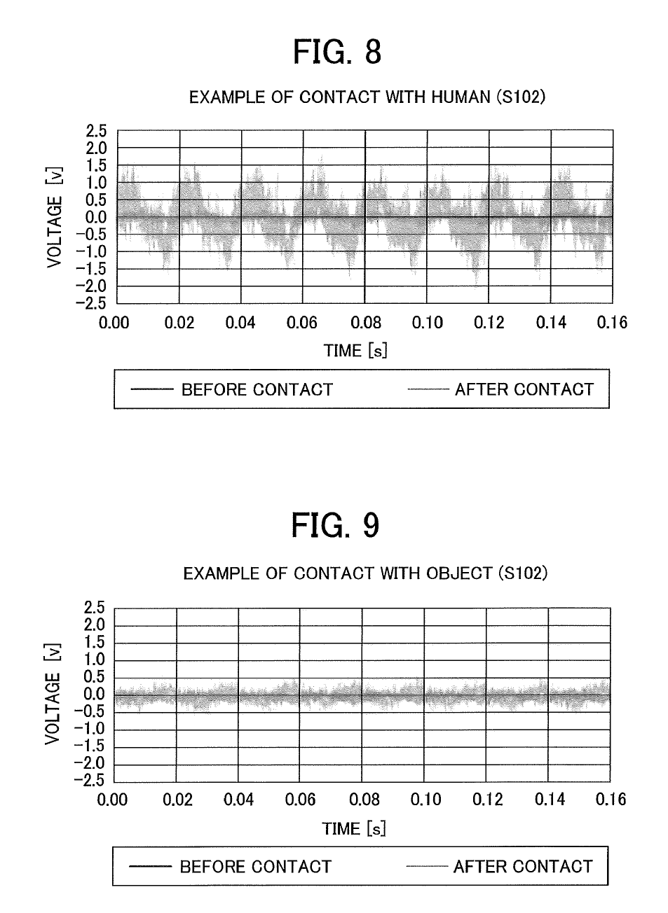

FIGS. 8 and 9 illustrate determination results of the human body 301 (person) and the object 302 (baggage) to be detected, indicated in Table 1. In FIGS. 8 and 9, the vertical axis indicates an output (voltage |V|) from the sensor, and the horizontal axis indicates time (s). FIG. 8 illustrates voltage characteristics (signals) before and after contact with the human body 301 (person), and FIG. 9 illustrates voltage characteristics (signals) before and after contact with the object 302 (baggage).

The detection electrode 33 confirmed a distinct difference between the signals before and after the contact with the human body 301 (person) illustrated in FIG. 8 and the voltage characteristics before and after the contact with the object 302 (baggage) illustrated in FIG. 9.

In step ST102 of the flowchart illustrated in FIG. 4, by setting the threshold V1 of the controller 100 to about 1 V, discrimination between the human body 301 and the object 302 was possible. The load detection sensor 4 (electrostatic capacity pressure sensor) could detect a surface pressure of the human body 301 (person) or the object 302 (baggage) against the detection surface 2A, and did not detect a surface pressure in a case of no load. Therefore, discrimination between contact with the human body 301 (human) or the object 302 (baggage) with respect to the detection surface 2A and no load was also possible.

As a comparative example, in a case where the detection electrode 33 is not disposed, a surface pressure of the human body 301 (person) or the object 302 (baggage) against the detection surface 2A was detected, but discrimination between the human body 301 (person) and the object 302 (baggage) was impossible.

The above fact indicates that it is possible to accurately discriminate whether a detection target of the chair 300 is the human body 301 (person) or the object 302 (baggage) using the sensor system 1 with the sensor 2 (sensor module 5). Furthermore, a surface pressure on the detection surface 2A can be monitored with the load detection sensor 4 (electrostatic capacity pressure sensor). Therefore, by setting a relation between a contact area and the detection load F in advance, it is also possible to discriminate among various objects 302 (baggage). That s, unlike a case of using a conventional sensor, it is possible to discriminate whether the human body 301 (person) is seated on the chair 300 or an object (for example, baggage such as a bag) is placed according to the type of output from one sensor 2 (sensor module 5) disposed on the chair 300 to perform detection.

In the above monitoring test, the example in which the sensor module 5 used as a seating sensor is disposed on the seating surface 300a of the wooden chair 300 has been described. However, if the sensor module 5 detects whether the human body 301 (person) is seated, the sensor module 5 may be disposed on a backrest 300b instead of the seating surface 300a, or may be disposed inside the seating surface 300a.

In a case where such a sensor system 1 is used as a seating system, by linking a result of contact/separation determination between the human body 301 and the object 302, for example, to an external information processing means as a separate signal (output), a system for managing a vacant seat state with a seating sensor can be obtained.

In a case where the type of the human body 301 (person) is divided into more divisions to be detected, a plurality of the thresholds C1 and C2 as the second determination values is set according to a change in output when the human body 301 (person) as a detection target is detected. For example, the values of the thresholds C1 and C2 are changed for each division of body weight, such as body weight 10 kg, 20 kg . . . , to be set. Taking weight as an example, as the weight gets heavier, the values of the thresholds C1 and C2 are increased. In this way, by changing the values of the thresholds C1 and C2 and setting the values in the controller 100, it is possible to classify and detect the human body 301 (person) seated on the chair 300 in more detail from a distribution of a weight and weight data of the human body 301 (person) seated on the chair 300. At this time, the thresholds are preferably set in a disposition environment for actual use in consideration of an effective load on the sensor 2. For example, the chair 300 alone includes many types, such as the chair 300 where the seating surface 300a is hard like the wooden bench of the present embodiment or the chair 300 where the seating surface 300a is soft like a cushion seat of an office chair. A sensor disposition surface has various hardnesses. In this way, in a case where the sensor 2 (sensor module 5) is disposed on the seating surfaces 300a having different hardnesses and a load is applied to the seating surfaces 300a, it is preferable to set a threshold considering that an effective load applied to a sensor surface is largely different between a hard seating surface and a soft seating surface.

Similarly, a plurality of the thresholds V1 as first determination values may be set. For example, the dielectric constants of muscles, fats, and the like which are components constituting the human body 301 are different from one another, and therefore the dielectric constant is different between a person with a muscular body and a person with a fat body. Therefore, it is estimated that there is a difference also in an output from the human body detection sensor 3 as the first detector that outputs a change in dielectric constant according to a nature (presence or absence of obesity) of a detection target. From this estimation, by setting the plurality of thresholds V1 and comparing the set thresholds V1 with the detection electrode voltage V output from the human body detection sensor 3, it is estimated that a nature of a person seated on the chair 300 (whether the person is obese) can be also detected.

A case where the target detected by the human body detection sensor 3 as the first detector is a human body has been described. However, the sensor 2 (sensor module 5) according to the present embodiment may be used for detecting a living creature such as an animal in place of detecting the human body 301.

In the present embodiment, the example in which the sensor system 1 is applied to the seating system has been described. However, an application range of the sensor system 1, the sensor module 5, or simply the sensor 2 is not limited to the above system. At least by applying the sensor system 1 to a case where one sensor detects a plurality of different parameters, including detection of a human body and an object other than the human body and detection of states of the detected human body and the detected object other than the human body, states of different kinds of objects can be detected accurately.

For example, the sensor system 1 can be also applied to a system that manages a vacant seat ratio and an occupancy ratio, a home care management system that manages a state of a home carer by detecting a human body, posture of the human body, and the like, and a crime prevention system that disposes the sensor module 5 on a floor or the like and detects a state of entrance to room based on detection of a human body and a pressure detection state.

The preferred embodiments of the present disclosure have been described above, but embodiments of the present disclosure are not limited to the specific embodiments. Unless otherwise specified in the above description, various modifications and changes are possible within the scope of the gist of the present invention described in the claims.

The effects of the above-described embodiments of the present disclosure indicate only a list of preferable effects obtained by embodiments of the present disclosure, and the effects of embodiments of the present disclosure are not limited to the effects described in the above-described embodiments of the present disclosure.

Each of the functions of the described embodiments may be implemented by one or more processing circuits or circuitry. Processing circuitry includes a programmed processor, as a processor includes circuitry. A processing circuit also includes devices such as an application specific integrated circuit (ASIC), digital signal processor (DSP), field programmable gate array (FPGA), and conventional circuit components arranged to perform the recited functions.

What is claimed is:

1. A sensor comprising:
a first detector to detect an electromagnetic noise varying according to a distance between the sensor and a human body, and to change an output according to the electromagnetic noise detected; and
a second detector to detect a detection load applied to a detection surface of the sensor, and to change an output according to the detection load.

2. The sensor according to claim 1,
wherein the first detector and the second detector are laminated, and the first detector is disposed closer to the detection surface than the second detector.

3. The sensor according to claim 1,
wherein the first detector includes a detection electrode to detect the electromagnetic noise.

4. The sensor according to claim 1,
wherein the second detector has a dielectric layer and a pair of electrodes facing each other via the dielectric layer, and at least the dielectric layer has flexibility.

5. A sensor system comprising:
the sensor according to claim 1; and
a controller to determine a detection target in contact with the detection surface according to an output from the sensor.

6. The sensor system according to claim 5,
wherein the detection target includes a human body and an object, and
wherein the controller determines contact between the sensor and the human body and contact between the sensor and the object based on comparison between an output from the first detector and a preset first determination value, and determines a load characteristic of the detection target based on comparison between an output from the second detector and a preset second determination value.
